(19) United States
(12) Patent Application Publication
(10) Pub. No.: US 2002/0089010 A1
(43) Pub. Date: Jul. 11, 2002

(54) Semiconductor device comprising a non-volatile memory cell

(76) Inventor: Hans U. Schroder, Drosselweg2 (DE)

Correspondence Address: Jack E Haken, U S Philips Corporation, 580 White Plains Road, Tarrytown, NY, 10591, US

(21) Appl. No.: 09/539,505

(22) Filed: Mar. 30, 2000

(30) Foreign Application Priority Data
Mar. 31, 1999 (EP) 99201020.7

(51) Int. Cl. H01L 29/76

(52) U.S. Cl. 257/314

(57) ABSTRACT

In customary EPROM processes, where the control gate is formed by a conductive poly layer on top of the floating gate, two poly layers are provided. An EPROM cell in accordance with the invention comprises a control gate formed by a well (10) of the second conductivity type, provided in a surface region (2) of a first conductivity type. The floating gate (9) extends above the well and is operated from said well by a thin gate oxide (11). The well (10) is provided with a contact region (14) of the second conductivity type, which is self-aligned with respect to the floating gate. As a result, the EPROM process only requires a single poly layer. Due to the fact that the well forming the control gate can be provided before the deposition of the poly layer, the EPROM process is compatible with standard CMOS processes. In addition, since the well is free of regions of the first conductivity type, the device is free of latch-up.

The invention relates to a semiconductor device comprising a semiconductor body which is provided at a surface with a non-volatile memory element in the form of a field effect transistor with a floating gate, said semiconductor body including a surface area of a first conductivity type which borders on the surface, in which surface area two surface regions are provided of the opposite, i.e. the second, conductivity type which form a source region and a drain region and are separated from each other by an intermediate channel region of the first conductivity type, the floating gate being arranged above the channel region in the form of a conductive layer which is electrically insulated from the channel region by an electrically insulating layer and extends over the electrically insulating layer and above a third surface region of the second conductivity type, hereinafter referred to as well, which extends from the surface to a greater depth in the semiconductor body than the source and drain regions of the transistor and is capacitively coupled to the floating gate via the electrically insulating layer, and said well being provided with a connection including a fourth surface region, hereinafter referred to as connection region, of the second conductivity type, which is provided in the well of the second conductivity type and has a higher doping concentration than the well. Such a device is known, inter alia, from U.S. Pat. No. 5,465,231 by Ohsaki.

Together with a number of similar cells, memory cells of the above-described type may form part of a memory for storing digital data in the form of electric charge on the floating gate. The cell may also be used, either individually or together with a few other cells, for analog applications, for example for offset compensation.

In conventional embodiments, the control gate is formed by a conductive layer which is provided above the floating gate and is electrically insulated therefrom by an intergate dielectric layer. Generally, both the floating gate and the control gate are made from polycrystalline, doped silicon (poly), so that the process includes at least two layers of poly. A memory cell with a poly layer is often desired, which can be attributed, among other things, to the fact that in standard CMOS processes only a single poly layer is used. Such a cell is proposed, inter alia, in the above-mentioned patent by Ohsaki. The cell described therein comprises an NMOS transistor with a floating gate, in which an n-well which serves as the control gate is provided next to the transistor in the p-type silicon. The floating gate extends above the n-well and is strongly capacitively coupled therewith. The n-well is provided with an electric connection with a heavily doped n-type contact region, which is provided in the well and which serves to apply suitable voltages to the well and hence the floating gate. The contact region is situated at the edge of the well. In the n-well, directly next to the floating gate (viewed in a direction transverse to the surface) two p-type regions are provided on either side of the gate, which are conductively connected to the n-type contact region. The p-type regions and the floating gate together form a p-MOS transistor the gate of which is connected to the floating gate of the n-MOS memory transistor and the source and drain of which are connected to the n-well. During writing or programming, a positive voltage is applied to the n-well, thereby causing a p-type inversion channel to be formed in the channel region of the p-MOS transistor. Since the potential of the floating gate increases at the same time, also in the n-MOS transistor an inversion channel is induced. The formation of the p-type inversion channel in the n-well is favorable because the potential of the floating gate is determined by the ratio of the capacitance between the gate and the p-type channel in the well to the capacitance between the gate and the n-type channel in the memory transistor. A disadvantage of this device resides in that the cell takes up relatively much space. In addition, computer simulations show that the potential of the p-type inversion layer in the n-well, and hence also the potential of the floating gate, depends upon the distance between the channel and the n-type contact region. In addition, the presence of the p-type regions in the well lead to the formation of parasitic pnpn structures which, at the relatively high write voltages, may give rise to latch-up problems.

It is an object of the invention to provide, inter alia, a non-volatile, one-layer poly cell in which these drawbacks are at least substantially obviated.

To achieve this, a semiconductor device of the type described in the opening paragraph is characterized in accordance with the invention in that the connection region and the floating gate are in alignment, the part of the well which, viewed on the surface, is situated directly next to the floating gate being entirely of the second conductivity type. The invention is, inter alia, based on the realization that as a result of the relatively light doping concentration in the n-well in a state of thermal equilibrium, the number of holes present in the well is already sufficient to form a p-type inversion layer below the gate at a rate which is sufficiently high for programming a memory cell. By virtue thereof, p-type regions situated next to the gate in the known device can be replaced by n-type regions of the same conductivity type as the n-well, which n-type regions can consequently be used as a connection for the n-well. Since p-type regions are not necessary, also the risk of latch-up is considerably reduced. Since, in addition, the n-type connection region can be provided directly next to the gate, the surface potential below the gate is always properly defined and no longer depends upon the distance between the floating gate and the connection region.

Advantageous embodiments are described in the sub-claims.

These and other aspects of the invention will be apparent from and elucidated with reference to an embodiment described hereinafter. In the drawings:

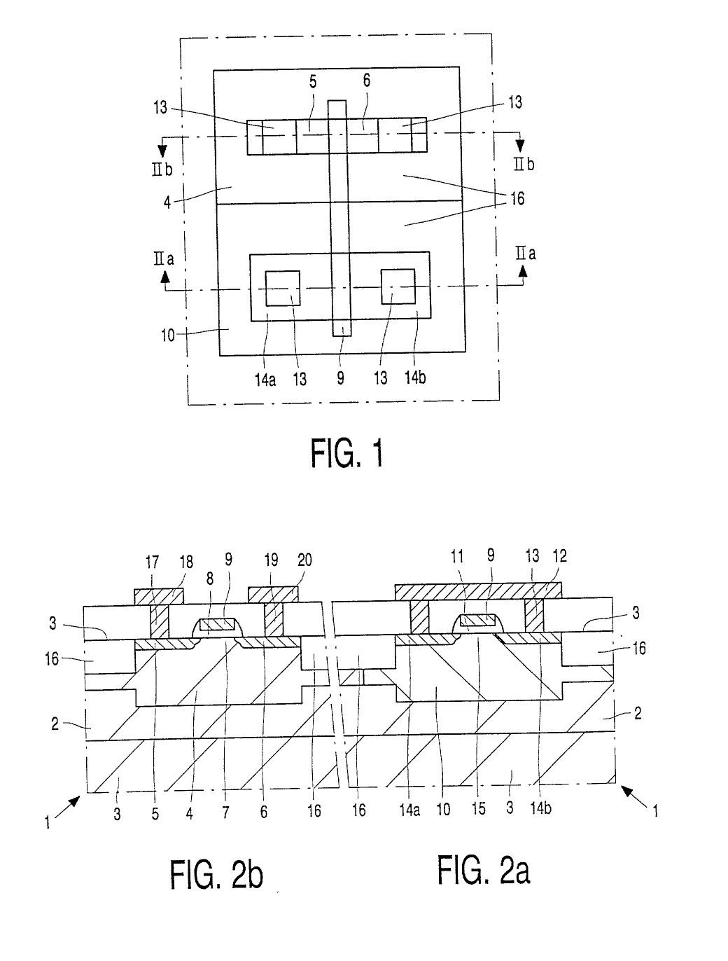

FIG. 1 is a schematic, plan view of a semiconductor device in accordance with the invention;

FIG. 2a is a sectional view of this semiconductor device, taken on the line IIa-IIa;

FIG. 2b is a sectional view of this device, taken on the line IIb-IIb;

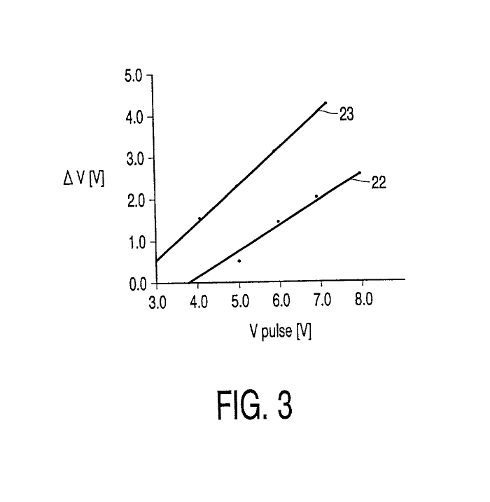

FIG. 3 shows the connection between the change of the threshold voltage and the voltage applied to the n-well.

In the drawing, a single non-volatile memory cell is shown. Together with a large number of other, similar cells, this cell may be arranged in a matrix of rows (words) and columns so as to form a non-volatile, programmable memory. In a different embodiment, the cell is used as a programmable element for, for example, offset compensation in an integrated circuit for analog applications.

The device comprises a semiconductor body 1 of, for example, silicon having a surface area 2 of a first conductivity type, in this example the p-type, which surface area borders on a surface 3. Here, the surface area 2 is formed by a layer which has been epitaxially deposited on the p-type substrate. In this embodiment, the doping concentrations of the layer 2 and the substrate 3 may be chosen independently. Of course, it is alternatively possible to use a semiconductor body having a different structure, such as a structure whereby the semiconductor body is exclusively formed by a uniformly doped substrate. For the memory element, a p-type well 4 is additionally formed in the p-type epi layer 2, in this example. The invention may however also be advantageously used in embodiments which do not comprise the well 4. The memory element is formed by a field effect transistor including an n-type source 5 and an n-type drain 6, which are provided as heavily doped surface regions in the p-type well 4. Above the channel region 7, between the source and the drain, and electrically insulated therefrom by a thin dielectric layer 8, in this example silicon oxide, there is provided a floating gate 9 which is entirely surrounded by electrically insulating material. The floating gate 9 extends over the surface and above a third surface region 10 of the second conductivity type, which in this example is the n-type, which extends, from the surface, deeper into the semiconductor body than the source and drain regions 5 and 6, and which will hereinafter be referred to as n-well. Said n-well is separated by a thin dielectric layer 11 from the floating gate 9 and capacitively strongly coupled to the gate 9 via the layer 11. To control the potential of the gate 9, the n-well 10 is provided with an electrical connection 12 which via contacts 13 and a heavily doped n-type connection region 14 in the n-well 10 is connected with the n-well. In accordance with the invention, the connection region and the gate 9 are in alignment, and, at least the part of the n-well which (seen on the surface) is situated directly next to the gate 9, is entirely of the n-type. In this example, the connection region 14 comprises two sub-regions 14a and 14b which are situated on either side of the gate 9 and which may be provided, in the same manner as the source and the drain, so as to be self-aligned with respect to the gate. Relative to the known device, space is saved in that an additional contact region at some distance from the gate is not required. Since there is no p-type region in the n-well 10, there is no lateral pnpn structure either between the n-well 10 and the p-well 4, so that also the risk of latch-up is reduced. Since, in addition, the connection region 14 is provided in a self-aligned manner with respect to the gate, the distance between the connection region 14 and the region 15 in the n-well below the floating gate 9, and hence the surface potential in the region 15, is well defined. Since the control gate of the non-volatile memory cell is formed by the n-well and, in addition, in a standard CMOS process, such a well is formed before the poly layer is deposited, the device can be manufactured using a standard one-layer poly-CMOS process. The n-well 10 and the p-well 4 are provided in active regions of the semiconductor body 1, which are defined by a pattern 16 of, for example, thick field oxide or a shallow trench isolation. The active region in the n-well has a larger width than the active region of the transistor, so that the capacitance between the gate 9 and the n-well is greater than the capacitance between the gate 9 and the channel region 7 in the p-well 4. The source 5 of the floating gate transistor is connected via a contact 17 and a conductor 18 to a node which is at a reference voltage, for example ground potential. The drain of this transistor is connected via a contact 19 to a conductor 20 which, in the case of a memory, forms a bit line (in which case the conductor 12 forms a word line). It is noted that the gate 9 is represented, in the example, by a poly strip of uniform width. Of course, this is not necessary. If desired, the poly strip may have a greater width above the n-well than above the p-well 4, for example to obtain a more favorable ratio between the capacitances of, on the one hand, the gate and, on the other hand, the p-well and the n-well. The cell can be operated in the following manner:

Writing: for programming, use can be made of an injection by hot electrons. For this purpose, a high positive voltage in the form of a pulse is applied via the word line 12 to the n-well 10. The capacitive coupling causes a part of this voltage to be transferred to the floating gate, so that an n-type channel is induced in the channel region 7 of the transistor. Source 5 and p-well 4 are grounded, while a positive voltage is applied to the drain 6. The value of the drain voltage must be high enough to form hot electrons. The drain current causes hot electrons to be injected on the floating gate 9 which, as a result, becomes negatively charged, so that the threshold voltage of the non-volatile memory cell increases. In FIG. 3, the change of the threshold voltage V (vertical axis) is plotted as a function of the voltage pulse V on the n-well (horizontal axis) for a specific embodiment. In the case of line 22, the drain voltage was 3 V, in the case of line 23, the drain voltage was 4 V. At a drain voltage of 2 V, the threshold voltage demonstrated practically no change. In all cases, the write time was approximately 10 ms. FIG. 3 shows that a favorable write condition can be obtained, inter alia, at a drain voltage of 4 V and a voltage of 7 V on the word line. In this case, the threshold voltage increases to approximately 4 V.

Reading: for reading, a voltage is applied to the word line 12 which is approximately the median value of the threshold voltage of the programmed cell and the initial threshold voltage of approximately 1 V. A low positive voltage, for example 0.15 V, is applied to the drain (if the source is grounded). Dependent upon the stored information, the transistor is either conducting or non-conducting.

Erasing: the cell can be erased in various ways. A favorable method was obtained in the relevant embodiment by exposure to UV radiation. However, other ways of erasing which are known per se, such as electrical erasing, may also be used.

It will be obvious that the invention is not limited to the example given herein, and that within the scope of the invention many variations are possible to those skilled in the art. For example, in the example given herein, the conductivity types may be reversed. For programming, use can also be made of the Fowler-Nordheim tunnel effect. In addition, the device can be erased electrically instead of by exposure to UV radiation.

1. A semiconductor device comprising a semiconductor body which is provided at a surface with a non-volatile memory element in the form of a field effect transistor with a floating gate, said semiconductor body including a surface area of a first conductivity type which borders on the surface, in which surface area two surface regions are provided of the opposite, i.e. the second, conductivity type which form a source region and a drain region and are separated from each other by an intermediate channel region of the first conductivity type, the floating gate being arranged above the channel region in the form of a conductive layer which is electrically insulated from the channel region by an electrically insulating layer and extends over the electrically insulating layer and above a third surface region of the second conductivity type, hereinafter referred to as well, which extends from the surface to a greater depth in the semiconductor body than the source and drain regions of the transistor and is capacitively coupled to the floating gate via the electrically insulating layer, and said well being provided with a connection including a fourth surface region, hereinafter referred to as connection region, of the second conductivity type, which is provided in the well of the second conductivity type and has a higher doping concentration than the well, characterized in that the connection region and the floating gate are in alignment, the part of the well which, viewed on the surface, is situated directly next to the floating gate being entirely of the second conductivity type.

2. A semiconductor device as claimed in claim 1, characterized in that the connection region comprises two sub-regions which extend on two opposite sides of the floating gate, namely, viewed on the surface, next to the floating gate in the well.

3. A semiconductor device as claimed in claim 1 or 2, characterized in that the thickness of the dielectric layer between the floating gate and the well is equal, or at least substantially equal to the thickness of the dielectric layer above the channel region of the transistor.

4. A semiconductor device as claimed in claim 3, characterized in that the well includes a peripheral portion which is covered by a part of the dielectric layer having a relatively large thickness, and a central portion which is covered by a part of the dielectric layer having a relatively small thickness, the floating gate and the sub-regions of the connection region situated on either side of the floating gate extending across the entire width of said central portion of the well.
